(19) United States
(12) Patent Application Publication
(10) Pub. No.: US 2020/0194551 A1
(43) Pub. Date: Jun. 18, 2020

(54) HIGH CONDUCTIVITY SOURCE AND DRAIN STRUCTURE FOR HEMT DEVICES

(71) Applicant: Intel Corporation, Santa Clara, CA (US)

(72) Inventors: Glenn GLASS, Portland, OR (US); Sansaptak DASGUPTA, Hillsboro, OR (US); Han Wui THEN, Portland, OR (US); Marko RADOSAVLJEVIC, Portland, OR (US); Paul FISCHER, Portland, OR (US); Anand MURTHY, Portland, OR (US)

(21) Appl. No.: 16/219,146

(22) Filed: Dec. 13, 2018

(51) Int. Cl. H01L 29/08; H01L 29/417; H01L 29/423; H01L 29/40; H01L 29/66; H01L 29/778; H01L 29/20

(52) U.S. Cl. CPC H01L 29/0847; H01L 29/41725; H01L 29/42356; H01L 29/2003; H01L 29/66462; H01L 29/778; H01L 29/402

(57) ABSTRACT

A device is disclosed. The device includes a polarization layer above a substrate, and a source that includes material that contains As or Sb that extends above the polarization layer. The source and the polarization layer are non-coplanar. The device also includes a drain that includes material that contains As or Sb that extends above the polarization layer. The drain and the polarization layer are non-coplanar. In addition, the device includes a source contact on the source and a drain contact on the drain.

### TECHNICAL FIELD

Embodiments of the disclosure pertain to source and drain structures for HEMT devices and, in particular, to high conductivity source and drain structures for HEMT devices.

### BACKGROUND

On resistance (Ron) refers to the total resistance between the drain and the source in a Metal Oxide Field Effect Transistor (MOSFET) when the MOSFET is “on.” In particular, Ron includes the total resistance in the current path between the drain and the source. Moreover, the total resistance includes the series of resistances traversed by the flow of current from the source to the drain. In general, for purposes of device performance, the lower the Ron the better.

Transistor Ron performance depends on the conductivity and the contact resistance of a transistor's source and drain material. In particular, maximal performance requires highly conductive, low contact resistance, source and drain material. In a conventional approach, group III nitrides with group IV doping is used. However, the use of nitrides is not satisfactory as nitrides are high bandgap, high resistance materials that exhibit high contact resistance. Tight pitch geometries require material that provides better contact resistance.

### BRIEF DESCRIPTION OF THE DRAWINGS

FIG. 1 shows a HEMT device according to an embodiment.

FIG. 2A illustrates a cross-section of an HEMT structure that includes a relaxed buffer stack, a polarization stack and a capping layer according to an embodiment.

FIG. 2B is an illustration of a cross-section of an enhancement mode transistor according to an embodiment.

FIG. 2C is an illustration of a cross-section of a depletion mode transistor according to an embodiment.

FIG. 2D is an illustration of a cross-section of an enhancement mode transistor with a field plate according to an embodiment.

FIG. 2E is an illustration of a cross-section of a depletion mode transistor with a field plate according to an embodiment.

FIG. 2F is an illustration of a cross-section of an enhancement mode transistor according to an embodiment.

FIG. 2G is an illustration of a cross-section of a depletion mode transistor according to an embodiment.

FIG. 2H is an illustration of a cross-section of an enhancement mode transistor with a field plate according to an embodiment.

FIG. 2I is an illustration of a cross-section of a depletion mode transistor with a field plate according to an embodiment.

FIG. 3 is a flowchart of a process for forming high conductivity source and drain structures for HEMT devices according to an embodiment.

FIG. 4 illustrates a computing device in accordance with one implementation of an embodiment.

FIG. 5 illustrates an interposer that includes one or more examples of an embodiment.

### DESCRIPTION OF THE EMBODIMENTS

High conductivity source and drain structures for HEMT devices are described. It should be appreciated that although embodiments are described herein with reference to example high conductivity source-drain structures for HEMT device implementations, the disclosure is more generally applicable to high conductivity source-drain structures for HEMT device implementations as well as other type high conductivity source-drain structures for HEMT device implementations. In the following description, numerous specific details are set forth, such as specific integration and material regimes, in order to provide a thorough understanding of embodiments of the present disclosure. It will be apparent to one skilled in the art that embodiments of the present disclosure may be practiced without these specific details. In other instances, well-known features, such as integrated circuit design layouts, are not described in detail in order to not unnecessarily obscure embodiments of the present disclosure. Furthermore, it is to be appreciated that the various embodiments shown in the Figures are illustrative representations and are not necessarily drawn to scale.

Certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

Transistor on-resistance (Ron) performance depends on the conductivity and the contact resistance of a transistor's source and drain material. In particular, maximal performance requires highly conductive, low contact resistance, source and drain material. In a previous approach, group III nitrides with group IV doping are used. However, the use of nitrides are not satisfactory because nitrides are high bandgap materials that have high resistance in general and high contact resistance in particular. The tight pitch geometries of current applications require improved contact resistance. In some previous approaches Si doped GaN or InAlN is used. However, Si doped GaN or InAlN does not provide adequate on-resistance performance.

An approach that addresses and overcomes the shortcomings of previous approaches is disclosed herein. As a part of the approach, a selective deposition of source and drain material is formed that has composition profiles that result in an improved Ron. Specifically, in an embodiment, the transistor source and the drain is formed from InAs doped with Si, Ge, C, or Sn, or InSb doped with Si, Ge, C, or Sn. In an embodiment, InAs doped with Si, Ge, C, or Sn or InSb doped with Si, Ge, C, or Sn can be used as a capping layer on GaN doped with Si, or on graded InxGa(1-x)N doped with Si where x=10-30% (the group III portion of the alloy is 10-30 atomic percent indium and 70-90 percent Ga). In an embodiment, interface contact metals (contact resistance reducing metals or conductors) can include but are not limited to In, Ti, Co, Si, Mg, Zn, Ni, Ta, Au, Au—Ge, Ru, Pd and W. In an embodiment, advantages in addition to low Ron can include lowered external resistance.

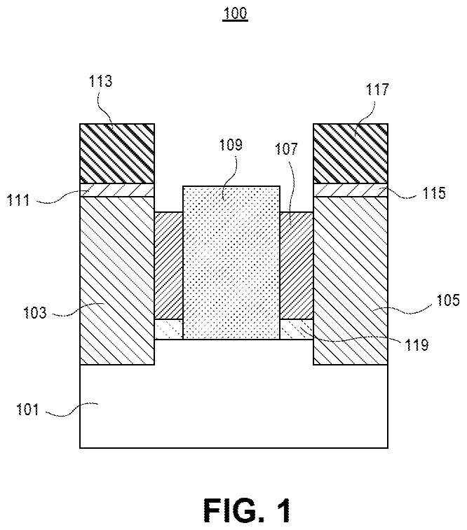

FIG. 1 shows an HEMT device 100 of an embodiment. In the FIG. 1 embodiment, the HEMT device 100 includes relaxed buffer stack 101, source 103, drain 105, first polarization layer 107, gate electrode 109, source contact resistance reducing metal 111, source contact 113, drain contact resistance reducing metal 115, drain contact 117, and second polarization layer 119. In other embodiments, the HEMT device 100 can include a thin oxide layer (not shown in FIG. 1) underneath the gate to form a MOS HEMT structure.

Referring to FIG. 1, the source 103 and the drain 105 are formed by selective deposition in recesses formed in the buffer stack 101 on first and second sides of the first polarization layer 107 and the second polarization 119. In an embodiment, as a part of the selective deposition process, source and drain regrowth material is formed on the exposed surfaces of selected material in the recesses. In an embodiment, the source 103 and the drain 105 are non-coplanar with respect to the top surface of the first polarization layer 107. For example, in an embodiment, the source 103 and the drain 105 extend above the top surface of the first polarization layer 107. In addition, in an embodiment, the source 103 and the drain 105 extend below the bottom surfaces of the first polarization layer 107 and the second polarization layer 119. In an embodiment, the source 103 and the drain 105 extend into a substrate that is formed underneath the buffer stack 101 (not shown). In an embodiment, the first polarization layer 107 is formed on the second polarization layer 119. In an embodiment, the first polarization layer 107 layer and the second polarization 119 are part of a polarization stack. In an embodiment, the first polarization layer 107 is thicker than the second polarization layer 119. In an embodiment, the first polarization layer 107 and the second polarization layer 119 cover a portion of a first and a second side surface of the gate electrode 109. The gate electrode 109 is formed on the buffer stack 101. The source contact resistance reducing metal 111 is formed on the source 103. The source contact 113 is formed on the source contact resistance reducing metal 111. The drain contact resistance reducing metal 115 is formed on the drain 105. The drain contact 117 is formed on the drain contact resistance reducing metal 115. The gate electrode 109 is formed on the buffer stack 101. The second polarization layer 119 is formed on the buffer stack 101. In an embodiment, the buffer stack 101 is formed above a substrate (not shown).

In an embodiment, the buffer stack 101 can be formed from material that includes group III-nitride alloys. For example, in an embodiment, the buffer stack 101 can be formed from GaN, InGaN or AlGaN or combinations thereof. In other embodiments, the buffer stack 101 can be formed from other materials. In an embodiment, the source 103 and the drain 105 can be formed from InAs doped with Si, Ge, C, or Sn, or InSb doped with Si, Ge, C, or Sn. In other embodiments, the source 103 and the drain 105 can be formed from other materials. In an embodiment, InAs doped with Si or InSb doped with Si can be used as a capping layer on GaN doped with Si or on graded InxGa(1-x)N doped with Si where x=10-30% (group III portion of the alloy is in the range of 15-30 atomic percent In and 90-70 percent Ga). In other embodiments, other capping layer materials on other materials or graded materials, having other mixtures, can be used. In an embodiment, the first polarization layer 107 can be formed from InAlN, AlGaN or InAlGaN. In other embodiments, the first polarization layer 107 can be formed from other materials. In an embodiment, the gate electrode 109 can be formed from Ni or Ta. In other embodiments, the gate electrode 109 can be formed from other materials. In an embodiment, the source contact resistance reducing metal 111 can be formed from In, Ti, Co, Si, Mg, Zn, Ni, Ta, Au, Au—Ge, Ru, Pd or W. In other embodiments, the source contact resistance reducing metal 111 can be formed from other materials. In an embodiment, the source contact 113 can be formed from Co, Ru or W. In other embodiments, the source contact 113 can be formed from other materials. In an embodiments, the drain contact resistance reducing metal 115 can be formed from In, Ti, Co, Si, Mg, Zn, Ni, Ta, Au, Au—Ge, Ru, Pd or W. In other embodiments, the drain contact resistance reducing metal 115 can be formed from other materials. In an embodiment, the drain contact 117 can be formed from Co, Ru or W. In other embodiments, the drain contact 117 can be formed from other materials. In an embodiment, the second polarization layer 119 can be formed from AlN. In other embodiments, the second polarization layer 119 can be formed from other materials.

In operation, when the gate-to-source voltage (VGS) of transistor 100 exceeds the threshold voltage (VTH), the transistor 100 turns on and the source 103 and drain 105 are connected by a channel that has a resistance that is referred to as the on resistance Ron. In an embodiment, the high conductivity and the low contact resistance of the source and the drain materials of transistor 100 enables maximal transistor on-resistance (Ron) performance. The herein described materials that are used to form the source 103 and the drain 105 of the HEMT device 100 provide better contact performance than does the materials such as the nitride based materials used to form the source and the drain regions in previous approaches. The source and the drain materials used in embodiments enable the low contact resistance and high conductivity that is required for high-frequency and high-power applications (e.g., RF and 5G). In addition, the source and the drain materials used in embodiments enable the low contact resistance and high conductivity needed to provide the tighter pitches required by such applications.

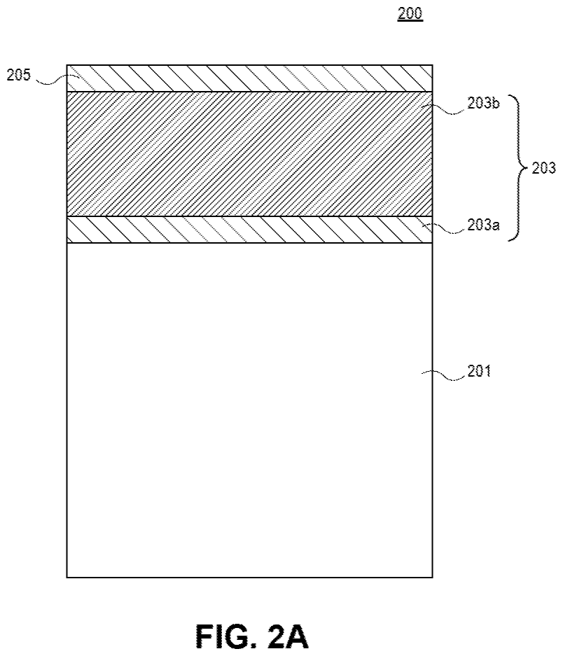

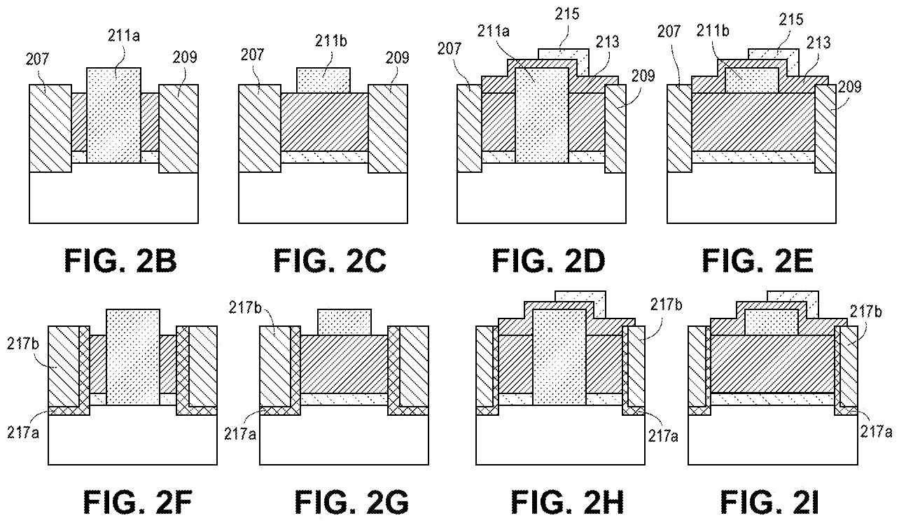

FIGS. 2A-2E show a cross-section of a HEMT structure 200 (in FIG. 2A) and respective devices that are derived from the HEMT structure 200 (in FIGS. 2B-2E) according to an embodiment.

Referring to FIG. 2A, after a plurality of operations the HEMT structure 200 includes a relaxed buffer stack 201, a polarization stack 203 and capping layer 205 (optional). In an embodiment, the polarization stack 203 includes AlN layer 203a and polarization layer 203b. In an embodiment, the polarization layer 203b can include but is not limited to InAlN, AlGaN or InAlGaN of various compositional ratios. In an embodiment, the capping layer 205 can include SiN or SiO2, or other insulating metal oxide or insulating nitride. In an embodiment, the insulating nitride can include SiN, BN or CN. In other embodiments, the insulating nitride can include other materials.

FIGS. 2B-2E are illustrations of cross-sections of respective devices derived from the HEMT structure 200 formed in operations subsequent to those that result in the cross-section shown in FIG. 2A, and that correspond to enhancement mode (FIG. 2B), depletion mode (FIG. 2C), enhancement mode with field plate (FIG. 2D) and depletion mode with field plate (FIG. 2D), type transistors.

Referring to FIG. 2B, as part of the fabrication of an enhancement mode device, after operations that result in the cross-section shown in FIG. 2A, source 207 and drain 209 regions are formed. In an embodiment, the source 207 and the drain 209 regions can be formed by selective deposition. In other embodiments, the source 207 and the drain 209 regions can be formed in other manners. In an embodiment, for enhancement mode devices, a gate recess is formed. In an embodiment, a gate dielectric can be formed in the gate recess (not shown). In other embodiments, a gate dielectric may not be formed in the gate recess (as shown in FIG. 2B). Subsequently, the gate electrode 211a is formed. In an embodiment, the gate electrode 211a can be formed by deposition. In other embodiments, the gate electrode 211a can be formed in other manners.

Referring to FIG. 2C, as part of the fabrication of a depletion mode device, after operations that result in the cross-section shown in FIG. 2A, source 207 and drain 209 regions are formed. In an embodiment, the source 207 and the drain 209 regions can be formed by selective deposition. In other embodiments, the source 207 and the drain 209 regions can be formed in other manners. In an embodiment, for depletion mode devices, a gate electrode 211b is formed on the polarization layer 203b (as shown in FIG. 2A). In other embodiments, a gate dielectric can be formed between the polarization layer 203b and the gate electrode 211b (not shown). In an embodiment, the gate electrode 211b can be formed by deposition. In other embodiments, the gate electrode 211b can be formed in other manners.

Referring to FIG. 2D, as part of the fabrication of an enhancement mode device, after operations that result in the cross-section shown in FIG. 2A, source 207 and drain 209 regions are formed. In an embodiment, the source 207 and the drain 209 regions can be formed by selective deposition. In other embodiments, the source 207 and the drain 209 regions can be formed in other manners. In an embodiment, for enhancement mode devices, a gate recess is formed. In an embodiment, a gate dielectric may not be formed in the recess (as shown in FIG. 2D). In other embodiments, a gate dielectric can be formed in the recess (not shown). Subsequently, the gate electrode 211a is formed. In an embodiment, the gate electrode 211a can be formed by deposition. In other embodiments, the gate electrode 211a can be formed in other manners. Thereafter, an insulator 213 is formed to cover a top portion of the gate electrode 211a. In an embodiment, a conductive field plate 215 is formed on the insulator to extend above the gate electrode 211a.

Referring to FIG. 2E, as part of the fabrication of a depletion mode device, after operations that result in the cross-section shown in FIG. 2A, source 207 and drain 209 regions are formed. In an embodiment, the source 207 and the drain 209 regions can be formed by selective deposition. In other embodiments, the source 207 and the drain 209 regions can be formed in other manners. In an embodiment, for depletion mode devices, a gate electrode 211b is formed on the polarization layer. In an embodiment, a gate dielectric may not be used (as shown in FIG. 2D). In other embodiments, a gate dielectric can be used. In an embodiment, the gate electrode 211b can be formed by deposition. In other embodiments, the gate electrode 211b can be formed in other manners. Thereafter, an insulator 213 is formed to cover a top portion of the gate electrode. In an embodiment, a conductive field plate 215 is formed on the insulator to extend above the gate electrode 211b.

FIGS. 2F-2I are illustrations of cross-sections of respective devices derived from the HEMT structure 200 formed in operations subsequent to those that result in the cross-section shown in FIG. 2A, and that correspond to enhancement mode (FIG. 2F), depletion mode (FIG. 2G), enhancement mode with field plate (FIG. 2H) and depletion mode with field plate (FIG. 2I), type transistors. Referring to FIGS. 2F-2I, these structures are formed in a manner similar to the manner in which the corresponding structures shown in FIGS. 2B-2E are formed, except that a first source/drain material 217a is formed in the source/drain recesses formed in the upper portion of the relaxed buffer stack, and a second material source/drain material 217b is formed in the source/drain recesses formed in the upper portion of the relaxed buffer stack above the first source/drain material 217a. In an embodiment, the first source/drain material 217a can be GaN doped with Si or graded InxGa(1-x)N doped with Si where x=10-30% (10-30 percent In and 90-70 percent Ga). In an embodiment, the second source/drain material 217b can include a capping layer of InAs doped with Si or a capping layer of InSb doped with Si.

In an embodiment, the selective source and drain material is easily distinguishable from source and drain material formed as part of the formation of a buffer and channel stack due to the non-coplanar nature of the source and drain material with respect to the polarization layer. In an embodiment, a grading of the composition of an InGaN material can be used to form the source and the drain. In an embodiment, the grading of the composition of the InGaN material used to form the source 207 and the drain 209 can be stepwise or gradual. In an embodiment, a contact resistance reducing conductor may or may not be formed between the semiconductor material used to form the source 207 and the drain 209 and the contact metal (e.g., plug). In an embodiment, the transistor can include enhancement mode and depletion mode type transistors and can include a field plate, diodes, and polarization layers and various stack types. The fraction of low bandgap (arsenide or antimonide) material in the source-drain can be zero percent, and up to 100 percent of the source-drain layer thickness. There may be low bandgap material exclusively in the source regions but nitride exclusively in the drain regions or conversely, nitride material exclusively in the source regions but low bandgap material exclusively in the drain regions. The fractions of the thickness of the two material types and the total thickness need not be fixed in the source and/or drain regions.

In an embodiment, the process of forming the HEMT device described herein can include a first epitaxial phase that results in the formation of a relaxed buffer stack, polarization layers, and optional passivation cap. In addition, a second epitaxial phase results in the formation of a source and drain layer, a gate recess, a gate dielectric and an electrode for enhancement mode devices. In an embodiment, as described herein the gate dielectric can be optional. In an embodiment, the transistor can included optional gate to drain field plates, partial/full deep isolation all the way to underlying layers and alumina or silicon nitride sidewall passivation. In other embodiments, the sidewall passivation can be formed from other materials.

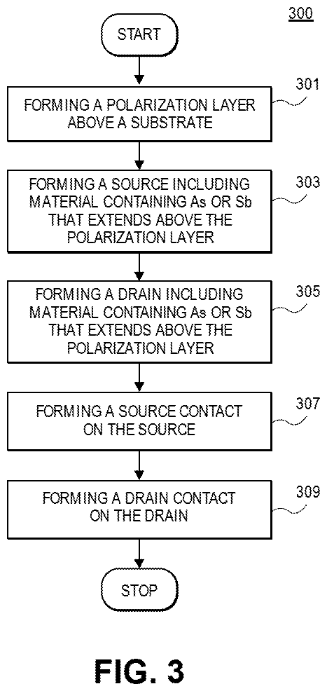

FIG. 3 is a flowchart of a process for forming high conductivity source and drain structures for HEMT devices according to an embodiment. Referring to FIG. 3, the process includes at 301, forming a polarization layer above a substrate. At 303, forming a source including material containing As (or Sb) that extends above the polarization layer. Thus, in an embodiment, the source and the polarization layer are non-coplanar. At 305, forming a drain including material containing As (or Sb) that extends above the substrate. Thus, in an embodiment the drain and the polarization layer are non-coplanar. At 307, forming a source contact that is coupled to the source. And, at 309, forming a drain contact that coupled to the drain. In an embodiment, the source and the drain includes InAs doped with Si, Ge, C or Sn as a capping layer on GaN doped with Si or graded InGaN doped with Si. In an embodiment, the source contact and the drain contact can include Co, Ru and W. In an embodiment, the device also includes a first resistance reducing metal that is coupled to the source contact and a second resistance reducing metal that is coupled to the drain contact. In an embodiment, the first resistance reducing metal and the second resistance reducing metal can include In, Ti, Co, Si, Mg, Zn, Ni, Ta, Au, Au—Ge, Ru, Pd, and W.

Implementations of embodiments of the invention may be formed or carried out on a substrate, such as a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the spirit and scope of the present invention.

A plurality of transistors, such as metal-oxide-semiconductor field-effect transistors (MOSFET or simply MOS transistors), may be fabricated on the substrate. In various implementations of the invention, the MOS transistors may be planar transistors, nonplanar transistors, or a combination of both. Nonplanar transistors include FinFET transistors such as double-gate transistors and tri-gate transistors, and wrap-around or all-around gate transistors such as nanoribbon and nanowire transistors. Although the implementations described herein may illustrate only planar transistors, it should be noted that the invention may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO2) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer is formed on the gate dielectric layer and may consist of at least one P-type workfunction metal or N-type workfunction metal, depending on whether the transistor is to be a PMOS or an NMOS transistor. In some implementations, the gate electrode layer may consist of a stack of two or more metal layers, where one or more metal layers are workfunction metal layers and at least one metal layer is a fill metal layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a workfunction that is between about 3.9 eV and about 4.2 eV.

In some implementations, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the invention, the gate electrode may consist of a combination of U-shaped structures and planar, non-U-shaped structures. For example, the gate electrode may consist of one or more U-shaped metal layers formed atop one or more planar, non-U-shaped layers.

In some implementations of the invention, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. And in further embodiments, one or more layers of metal and/or metal alloys may be used to form the source and drain regions.

One or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (SiO2), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

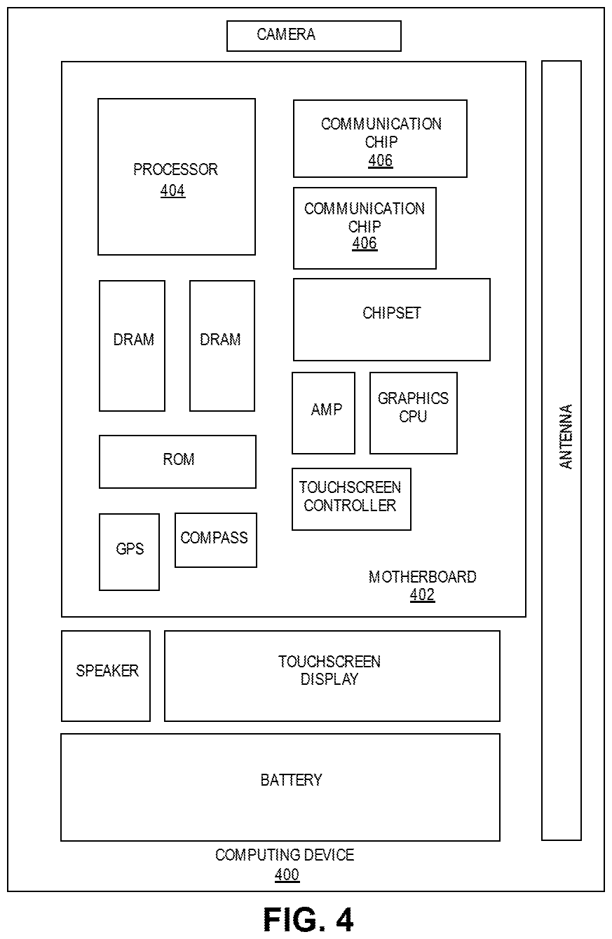

FIG. 4 illustrates a computing device 400 in accordance with one implementation of the invention. The computing device 400 houses a board 402. The board 402 may include a number of components, including but not limited to a processor 404 and at least one communication chip 406. The processor 404 is physically and electrically coupled to the board 402. In some implementations the at least one communication chip 406 is also physically and electrically coupled to the board 402. In further implementations, the communication chip 406 is part of the processor 404.

Depending on its applications, computing device 400 may include other components that may or may not be physically and electrically coupled to the board 402. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 406 enables wireless communications for the transfer of data to and from the computing device 400. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 406 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 400 may include a plurality of communication chips 406. For instance, a first communication chip 406 may be dedicated to shorter range wireless communications such as Wi-Fi and Bluetooth and a second communication chip 406 may be dedicated to longer range wireless communications such as GPS, EDGE, GPRS, CDMA, WiMAX, LTE, Ev-DO, and others.

The processor 404 of the computing device 400 includes an integrated circuit die packaged within the processor 404. In some implementations of the invention, the integrated circuit die of the processor includes one or more devices, such as MOS-FET transistors built in accordance with implementations of the invention. The term “processor” may refer to any device or portion of a device that processes electronic data from registers and/or memory to transform that electronic data into other electronic data that may be stored in registers and/or memory.

The communication chip 406 also includes an integrated circuit die packaged within the communication chip 406. In accordance with another implementation of the invention, the integrated circuit die of the communication chip includes one or more devices, such as MOS-FET transistors built in accordance with implementations of the invention.

In further implementations, another component housed within the computing device 400 may contain an integrated circuit die that includes one or more devices, such as MOS-FET transistors built in accordance with implementations of the invention.

In various implementations, the computing device 400 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 400 may be any other electronic device that processes data.

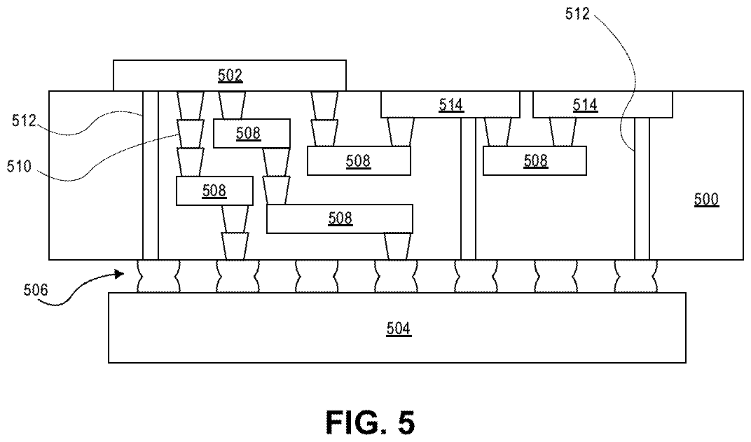

FIG. 5 illustrates an interposer 500 that includes one or more embodiments of the invention. The interposer 500 is an intervening substrate used to bridge a first substrate 502 to a second substrate 504. The first substrate 502 may be, for instance, an integrated circuit die. The second substrate 504 may be, for instance, a memory module, a computer motherboard, or another integrated circuit die. Generally, the purpose of an interposer 500 is to spread a connection to a wider pitch or to reroute a connection to a different connection. For example, an interposer 500 may couple an integrated circuit die to a ball grid array (BGA) 506 that can subsequently be coupled to the second substrate 504. In some embodiments, the first and second substrates 502/504 are attached to opposing sides of the interposer 500. In other embodiments, the first and second substrates 502/504 are attached to the same side of the interposer 500. And in further embodiments, three or more substrates are interconnected by way of the interposer 500.

The interposer 500 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer may include metal interconnects 508 and vias 510, including but not limited to through-silicon vias (TSVs) 512. The interposer 500 may further include embedded devices 514, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 500. In accordance with embodiments of the invention, apparatuses or processes disclosed herein may be used in the fabrication of interposer 500.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of the present disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of the present application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

The following examples pertain to further embodiments. The various features of the different embodiments may be variously combined with some features included and others excluded to suit a variety of different applications.

Example embodiment 1: A device including a polarization layer above a substrate, a source including a material containing As that extends above the polarization layer, wherein the source and the polarization layer are non-coplanar, a drain including the material containing As that extends above the polarization layer, wherein the drain and the polarization layer are non-coplanar, a source contact on the source, and a drain contact on the drain.

Example embodiment 2: The device of example embodiment 1, wherein the material containing As includes InAs.

Example embodiment 3: The device of example embodiment 1, wherein the material containing As includes InAs doped with Si, Ge, C or Sn.

Example embodiment 4: The device of example embodiment 1, wherein the source and the drain includes InAs doped with Si, Ge, C or Sn as a capping layer on GaN doped with Si or graded InGaN doped with Si.

Example embodiment 5: The device of example embodiment 1 2, 3 or 4, wherein the source contact and the drain contact include Co, Ru, or W.

Example embodiment 6: The device of example embodiment 1, further comprising a first resistance reducing conductor coupled to the source contact and a second resistance reducing conductor coupled to the drain contact.

Example embodiment 7: The device of example embodiment 1, further comprising a gate electrode configured to lie above the polarization layer in a depletion mode transistor and to extend into the polarization layer in an enhancement mode transistor.

Example embodiment 8: A device including a polarization layer above a substrate, a source including material containing Sb that extends above the polarization layer, wherein the source and the polarization layer are non-coplanar, a drain including material containing Sb that extends above the polarization layer, wherein the drain and the polarization layer are non-coplanar, a source contact on the source, and a drain contact on the drain.

Example embodiment 9: The device of example embodiment 8, wherein the material containing Sb includes InSb.

Example embodiment 10: The device of example embodiment 8, wherein the material containing As includes InSb doped with Si, Ge, C or Sn.

Example embodiment 11: The device of example embodiment 8, wherein the source and the drain includes InSb doped with Si, Ge, C or Sn as a capping layer on GaN doped with Si or graded InGaN doped with Si.

Example embodiment 12: The device of example embodiment 8 9, 10 or 11, wherein the source contact and the drain contact includes Co, Ru, or W.

Example embodiment 13: The device of example embodiment 8, further comprising a first resistance reducing conductor on the source contact and a second resistance reducing conductor on the drain contact.

Example embodiment 14: The device of example embodiment 8, further comprising a gate electrode configured to lie above the polarization layer in a depletion mode transistor and to extend into the polarization layer in an enhancement mode transistor.

Example embodiment 15: A method including forming a polarization layer above a substrate, forming a source including material containing As that extends above the polarization layer, wherein the source and the polarization layer are non-coplanar, forming a drain including material containing As that extends above the polarization layer, wherein the drain and the polarization layer are non-coplanar, forming a source contact on the source, and forming a drain contact on the drain.

Example embodiment 16: The method of example embodiment 15, wherein the material containing As includes InAs.

Example embodiment 17: The method of example embodiment 15, wherein the material containing As includes InAs doped with Si, Ge, C or Sn.

Example embodiment 18: The method of example embodiment 15, wherein the source and the drain includes InAs doped with Si as a capping layer on GaN doped with Si or graded InGaN doped with Si.

Example embodiment 19: The method of example embodiment 15, 16, 17, or 18, wherein the source contact and the drain contact includes Co, Ru, or W.

Example embodiment 20: The method of example embodiment 15, further comprising form a first resistance reducing conductor on the source contact and a second resistance reducing conductor on the drain contact.

What is claimed is:

1. A device, comprising:
a polarization layer above a substrate;
a source including a material containing As that extends above the polarization layer, wherein the source and the polarization layer are non-coplanar;
a drain including the material containing As that extends above the polarization layer, wherein the drain and the polarization layer are non-coplanar;
a source contact on the source; and
a drain contact on the drain.

2. The device of claim 1, wherein the material containing As includes InAs.

3. The device of claim 1, wherein the material containing As includes InAs doped with Si, Ge, C or Sn.

4. The device of claim 1, wherein the source and the drain includes InAs doped with Si as a capping layer on GaN doped with silicon or graded InGaN doped with Si.

5. The device of claim 1, wherein the source contact and the drain contact includes Co, Ru, or W.

6. The device of claim 1, further comprising a first resistance reducing conductor coupled to the source contact and a second resistance reducing conductor coupled to the drain contact.

7. The device of claim 1, further comprising a gate electrode configured to lie above the polarization layer in a depletion mode transistor and to extend into the polarization layer in an enhancement mode transistor.

8. A device, comprising:
a polarization layer above a substrate;
a source including a material containing Sb that extends above the polarization layer, wherein the source and the polarization layer are non-coplanar;
a drain including material containing Sb that extends above the polarization, wherein the drain and the polarization layer are non-coplanar;
a source contact on the source; and
a drain contact on the drain.

9. The device of claim 8, wherein the material containing Sb includes InSb.

10. The device of claim 8, wherein the material containing As includes InSb doped with Si, Ge, C or Sn.

11. The device of claim 8, wherein the source and the drain includes InSb doped with Si as a capping layer on GaN doped with silicon or graded InGaN doped with Si.

12. The device of claim 8, wherein the source contact and the drain contact includes Co, Ru, or W.

13. The device of claim 8, further comprising a first resistance reducing conductor on the source contact and a second resistance reducing conductor on the drain contact.

14. The device of claim 8, further comprising a gate electrode configured to lie above the polarization layer in a depletion mode transistor and to extend into the polarization layer in an enhancement mode transistor.

15. A method, comprising:
forming a polarization layer above a substrate;
forming a source including material containing As or Sb that extends above the polarization layer, wherein the source and the polarization layer are non-coplanar;
forming a drain including material containing As or Sb that extends above the polarization layer, wherein the drain and the polarization layer are non-coplanar;
forming a source contact on the source; and
forming a drain contact on the drain.

16. The method of claim 15, wherein the material containing As or Sb includes InAs or InSb.

17. The method of claim 15, wherein the material containing As or Sb includes InAs or InSb doped with Si, Ge, C or Sn.

18. The method of claim 15, wherein the source and the drain includes InAs or InSb doped with Si as a capping layer on GaN doped with silicon or graded InGaN doped with Si.

19. The method of claim 15, wherein the source contact and the drain contact includes Co, Ru, or W.

20. The method of claim 15, further comprising a first resistance reducing conductor on the source contact and a second resistance reducing conductor on the drain contact.
